(19) United States
(12) Patent Application Publication
(10) Pub. No.: US 2024/0344198 A1
(43) Pub. Date: Oct. 17, 2024

(54) BACKING PLATE AND DIFFUSER PLATE ASSEMBLY

(71) Applicant: Applied Materials, Inc., Santa Clara, CA (US)

(72) Inventors: Guangwei Sun, San Jose, CA (US); Jeffrey A. Kho, Monte Sereno, CA (US); Lai Zhao, Campbell, CA (US)

(21) Appl. No.: 18/630,981

(22) Filed: Apr. 9, 2024

Related U.S. Application Data
(60) Provisional application No. 63/458,910, filed on Apr. 12, 2023.

(51) Int. Cl. C23C 16/455

(52) U.S. Cl. CPC C23C 16/45559; C23C 16/45544

(57) ABSTRACT

An assembly includes a backing plate and a diffuser plate configured to be disposed under the backing plate. The diffuser plate forms purge holes in a first region of the diffuser plate between a diffuser plate upper surface and a diffuser plate lower surface. The diffuser plate forms perforated area holes in a second region of the diffuser plate between the diffuser plate upper surface and the diffuser plate lower surface. Each of the perforated area holes has a first width at the diffuser plate upper surface and a second width at the diffuser plate lower surface. The second width is larger than the first width.

### RELATED APPLICATION

This application claims benefit of U.S. Provisional Application No. 63/458,910, filed Apr. 12, 2023, the contents of which are incorporated by reference herein in their entirety.

### TECHNICAL FIELD

Embodiments of the present disclosure relate to assemblies, such as those used in association with substrate processing systems, and in particular to backing plate and diffuser plate assemblies.

### BACKGROUND

In substrate processing and other electronics processing, processing chambers are used to perform substrate processing operations. Different gases are provided into the processing chamber to perform substrate processing operations.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, an assembly includes a backing plate and a diffuser plate configured to be disposed under the backing plate. The diffuser plate forms a plurality of purge holes in a first region of the diffuser plate between a diffuser plate upper surface and a diffuser plate lower surface. The diffuser plate forms a plurality of perforated area holes in a second region of the diffuser plate between the diffuser plate upper surface and the diffuser plate lower surface. In some embodiments, each of the plurality of perforated area holes has a first width at the diffuser plate upper surface and a second width at the diffuser plate lower surface. The second width is larger than the first width. In some embodiments, each of the plurality of perforated area holes has a same width from the diffuser plate upper surface to the diffuser plate lower surface.

In another aspect of the disclosure, an assembly includes a diffuser plate and a backing plate configured to be disposed above the diffuser plate. A backing plate lower surface of the backing plate forms perimeter dead zone protrusion. The backing plate lower surface forms a recess surrounded by the perimeter dead zone protrusion. A dead zone height between a diffuser plate upper surface of the diffuser plate and the perimeter dead zone protrusion is smaller than a gap height between the diffuser plate upper surface and the backing plate lower surface at the recess.

In another aspect of the disclosure, an assembly includes a backing plate including a backing plate lower surface that forms a perimeter dead zone protrusion. The assembly further includes a diffuser plate configured to be disposed under the backing plate. The diffuser plate forms a plurality of purge holes between a diffuser plate upper surface and a diffuser plate lower surface. The plurality of purge holes are configured to be disposed under the perimeter dead zone protrusion.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 illustrates a system including a backing plate and a diffuser plate, according to certain embodiments.

FIG. 2 illustrates a system including a backing plate and a diffuser plate, according to certain embodiments.

FIGS. 3A-B illustrate a backing plate, according to certain embodiments.

FIGS. 4A-B illustrate a diffuser plate, according to certain embodiments.

FIG. 5 illustrates a method of using a backing plate and diffuser plate assembly, according to certain embodiments.

### DETAILED DESCRIPTION OF EMBODIMENTS

Embodiments described herein are related to backing plate and diffuser plate assemblies (e.g., backing plate and diffuser plate for Atomic Layer Deposition (ALD)).

Substrate processing systems are used to process substrates. A substrate is transferred into a processing chamber via a robot (e.g., a transfer chamber robot). The processing chamber is sealed and a substrate processing operations (e.g., ALD, chemical vapor deposition (CVD), plasma-enhanced CVD (PECVD), plasma-enhanced ALD (PEALD), etch, etc.) are performed on the substrate. Different gases are used to perform different operations. For example, a precursor gas can be provided into the processing chamber, followed by an inert gas to attempt to flush out (e.g., purge) the precursor gas, and then followed by a reactant gas being provided into the processing chamber.

In some conventional systems, a first gas (e.g., precursor gas) is not completely flushed out by inert gas, causing the reactant gas to react with the non-flushed precursor gas. This causes particles which interfere with the substrate processing operations and quality of the substrate. This results in substrate defects, inconsistent substrate performance, decreased yield, etc.

In some conventional systems, the purge duration and purge flow rate are increased to attempt to flush out more of the precursor. This increases the gas and energy used, increases the duration of operations, and decreases the substrate yield.

The components, assemblies, systems, and methods disclosed herein provide a backing plate and diffuser plate assembly that solve these and other problems of conventional systems.

An assembly (e.g., backing plate and diffuser plate assembly, ALD tool, processing chamber) includes a backing plate and a diffuser plate disposed under the backing plate. An inner volume is formed by the lower surface of the backing plate and an upper surface of the diffuser plate. Gas flows through a channel of the backing plate into the inner volume and from the inner volume through holes of the diffuser plate to a substrate (e.g., disposed on a susceptor below the assembly in the processing chamber).

In some embodiments, the diffuser plate forms purge holes (e.g., perimeter purge holes, holes within the first 20% of the total width of the diffuser plate, within the first 10% of the total width of the diffuser plate, within the first 5% of the total width of the diffuser plate, etc.) and perforated area holes (e.g., cone holes, holes that have a larger diameter at one end than the other end, holes that have cone-like shapes, etc.) between a diffuser plate upper surface and a diffuser plate lower surface. The purge holes are formed in a perimeter portion of the diffuser plate and the perforated area holes are formed in a perforated portion of the diffuser plate, where the perimeter portion surrounds the perforated portion.

In some embodiments, a backing plate lower surface of the backing plate forms perimeter dead zone protrusion (e.g., dead zone filler) and a recess surrounded by the perimeter dead zone protrusion. A dead zone height (e.g., about 1 to about 5 millimeters (mm)) between the diffuser plate upper surface and the perimeter dead zone protrusion is smaller than a gap height (e.g., about 10 to about 20 mm) between the diffuser plate upper surface and the backing plate lower surface at the recess. The dead zone height may be about 5% to about 50% (e.g., about 10% to about 50%, about 10% to about 20%, about 5% to about 25%, about 10% to about 25%, about 25% to about 50%, etc.) the gap height. In some embodiments, the purge holes are configured to be disposed under the perimeter dead zone protrusion.

The dead zone height (e.g., about 1 to about 5 mm) is not so small that the dead zone protrusion touches the diffuser plate due to manufacturing tolerance and is not so large that there is more residual gas in the dead zone to purge. The dead zone height may not change relative to the gap height.

The components, systems, and methods disclosed herein have advantages over conventional solutions. The dead zone protrusion of the present disclosure prevents gas from not being flushed, which causes less reaction of reactant gas with non-flushed precursor gas compared with conventional solutions. The purge holes allow more precursor gas to be flushed out of the inner volume compared to conventional solutions. The present disclosure produces less particles, interferes less with substrate processing operations, and has improved substrate processing operations compared to conventional solutions. The present disclosure has less substrate defects, more consistent substrate performance, increased yield, etc. compared to conventional solutions. The present disclosure uses less gas and energy than conventional solutions. The present disclosure decreases duration of operations and increases substrate yield compared to conventional solutions.

Although some embodiments of the present disclosure are described with relation to ALD systems and processing chambers, in some embodiments, the present disclosure may be used in other types of systems (e.g., CVD, etc.) and/or other types of equipment.

Although some embodiments of the present disclosure are described with relation to flow of precursors, inert gas, and reactant gases, in some embodiments, the present disclosure may be used with one or more types of fluid (e.g., same gas, different gases, liquid(s), liquid and gas, etc.).

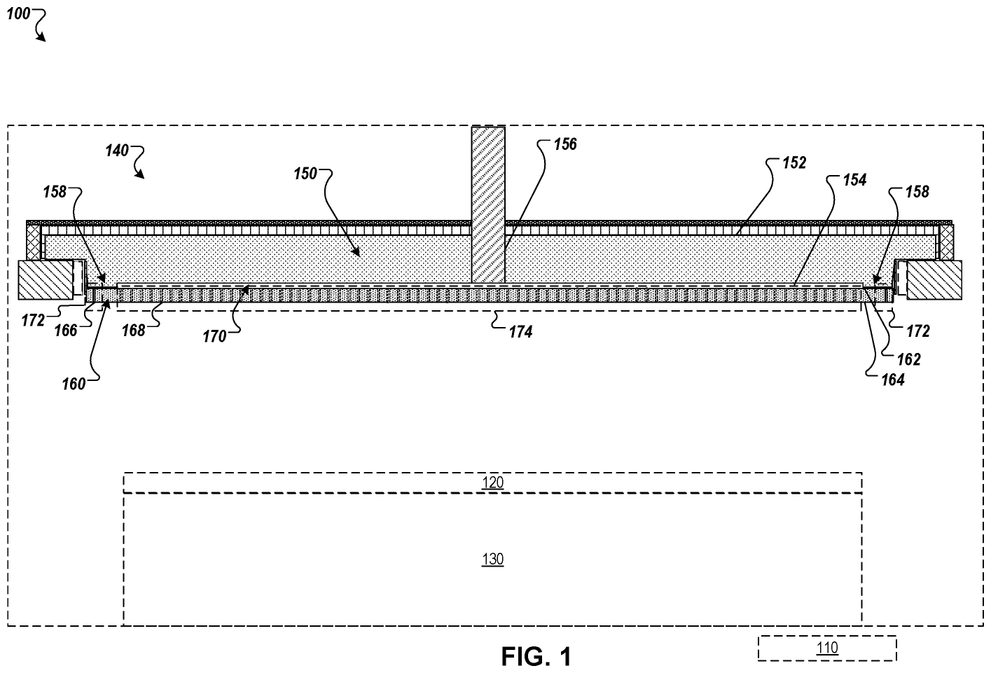

FIG. 1 illustrates a system 100 including a backing plate 150 (e.g., lid plate, upper surface of processing chamber, etc.) and a diffuser plate 160 (e.g., shower head, face plate, etc.), according to certain embodiments.

System 100 may be a processing chamber of a substrate processing chamber, such as a sequential ALD system, plasma treatment chamber, an annealing chamber, physical vapor deposition (PVD) chamber, chemical vapor deposition (CVD) chamber, ion implantation chamber, etch chamber, deposition chamber (e.g., atomic layer deposition (ALD) chamber, chemical vapor deposition (CVD) chamber, physical vapor deposition (PVD) chamber, and/or plasma enhanced (PE) versions thereof, such as PEALD, PECVD, PEPVD, etc.), anneal chamber, or the like. In some embodiments, the processing chamber is configured to receive one or more fluids (e.g., gas, plasma, etc.) from one or more sources (e.g., high density plasma (HDP) source, precursor gas source, inert gas source, reactant gas source, fluid supply, pump, valve, etc.).

The system 100 may receive a substrate 120 (e.g., into an interior volume of the processing chamber) via an end effector of a transfer chamber robot. A substrate 120 may refer to a wafer, semiconductor, glass, glass substrate, electronic device, glass device, display device, and/or the like.

The system 100 may include a susceptor 130 (e.g., electrostatic chuck, a vacuum chuck, a workpiece support surface, and/or the like) in on which the substrate 120 may be placed. An assembly 140 (e.g., backing plate and diffuser plate assembly) may be disposed above the substrate 120 and/or susceptor 130. The assembly 140 may provide gases into the system 100 (e.g., into an interior volume of the processing chamber) for processing of the substrate 120.

The assembly 140 includes a backing plate 150 and a diffuser plate 160. The backing plate 150 is disposed on the diffuser plate 160.

The backing plate 150 includes a backing plate upper surface 152 and a backing plate lower surface 154. The backing plate 150 forms a backing plate gas channel 156 from the backing plate upper surface 152 to the backing plate lower surface 154.

The diffuser plate 160 includes a diffuser plate upper surface 162 and a diffuser plate lower surface 164. The diffuser plate 160 forms purge holes 166 (e.g., perimeter purge holes, holes within the first 20% of the total width of the diffuser plate, within the first 10% of the total width of the diffuser plate, within the first 5% of the total width of the diffuser plate, etc.) between the diffuser plate upper surface 162 and the diffuser plate lower surface 164. In some embodiments, each of the purge holes 166 have a diameter of about 1 to about 2 mm (e.g., about 1.5 mm). The diffuser plate 160 forms perforated area holes 168 (e.g., cone holes, holes that have a larger diameter at one end than the other end, holes that have cone-like shapes, etc.) between the diffuser plate upper surface 162 and the diffuser plate lower surface 164.

The diffuser plate 160 forms the purge holes 166 in a perimeter portion 172 (e.g., first region, perimeter region) of the diffuser plate and the diffuser plate 160 forms the perforated area holes 168 in a perforated portion 174 (e.g., second region, central region) of the diffuser plate 160. The perimeter portion 172 surrounds the perforated portion 174 (e.g., the first region is disposed around the second region). In some embodiments, each of the perforated area holes 168 has a first width (e.g., upper width, upper diameter) at the diffuser plate upper surface 162 and a second width (e.g., lower width, lower diameter) at the diffuser plate lower surface 164, where the second width is larger than the first width. In some embodiments, each of the perforated area holes 168 has a same width from the diffuser plate upper surface 162 to the diffuser plate lower surface 164. In some embodiments, at least a subset of the perforated area holes 168 has a first width at the diffuser plate upper surface 162 and a second width at the diffuser plate lower surface 164, where the second width is larger than the first width. In some embodiments, at least a subset of the perforated area holes 168 has a same width from the diffuser plate upper surface 162 to the diffuser plate lower surface 164.

The assembly 140 forms an inner volume 170 between the backing plate lower surface 154 and the diffuser plate upper surface 162. Gas is to be provided via the backing plate gas channel 156 to the inner volume 170 and from the inner volume 170 via the perforated area holes 168 to the substrate 120.

In some embodiments, the backing plate lower surface 154 of the backing plate 150 forms a perimeter dead zone protrusion 158 configured to be disposed proximate the diffuser plate upper surface 162. The purge holes 166 may be below the perimeter dead zone protrusion 158. The perforated area holes 168 may be below the recess formed by the backing plate 150.

In some embodiments, each of the purge holes 166 have a substantially uniform diameter (e.g., from diffuser plate upper surface 162 to diffuser plate lower surface 164, purge holes 166 have a substantially same diameter and each of the purge holes 166 has a substantially same diameter as each other). The purge holes 166 are configured to provide an exit for residual gas in a dead zone between the backing plate 150 (e.g., perimeter dead zone protrusion 158) and the diffuser plate 160.

The backing plate lower surface 154 of the backing plate 150 forms a recess (e.g., central recess) configured to be disposed above a perforated portion 174 of the diffuser plate 160 that forms the perforated area holes 168. The recess (e.g., formed by the backing plate lower surface 154) is surrounded by the perimeter dead zone protrusion. A dead zone height between a diffuser plate upper surface 162 of the diffuser plate 160 and the perimeter dead zone protrusion is smaller than a gap height between the diffuser plate upper surface 162 and the backing plate lower surface 154 at the recess. The dead zone height may be about 5% to about 50% (e.g., about 10% to about 50%, about 10% to about 20%, about 5% to about 25%, about 25% to about 50%, etc.) the height of the gap height. In some embodiments, the dead zone height is about 1 to about 5 mm (e.g., about 3 mm). In some embodiments, the gap height is about 10 to about 20 mm (e.g., 13 mm). The dead zone height (e.g., about 1 to about 5 mm) is not so small that the dead zone protrusion touches the diffuser plate due to manufacturing tolerance and is not so large that there is more residual gas in the dead zone to purge. The dead zone height may not change relative to the gap height.

In some embodiments, each of the perforated area holes 168 includes an upper uniform portion (e.g., substantially same diameter from top to bottom of upper uniform portion) and a lower cone-shaped portion (e.g., transitions from the diameter of the uniform portion to a larger diameter at the diffuser plate lower surface 164). In some embodiments, the cone-shaped portion can be one or more of cylindrical, triangular frustum, cubical, rectangular prism, etc.

In some embodiments, the system is a sequential ALD system that includes the assembly 140.

Gas (e.g., precursor gas, inert gas, reactant gas, etc.) is configured to flow through the backing plate gas channel 156 to the inner volume 170 and through the perforated area holes 168 to locations above the substrate 120.

In some embodiments, a controller 110 controls various aspects of the system 100 (e.g., processing chamber), robot, and/or substrate processing system. The controller 110 is and/or includes a computing device such as a personal computer, a server computer, a programmable logic controller (PLC), a microcontroller, and so on. The controller 110 includes one or more processing devices, which, in some embodiments, are general-purpose processing devices such as a microprocessor, central processing unit, or the like. More particularly, in some embodiments, the processing device is a complex instruction set computing (CISC) microprocessor, reduced instruction set computing (RISC) microprocessor, very long instruction word (VLIW) microprocessor, or a processor implementing other instruction sets or processors implementing a combination of instruction sets. In some embodiments, the processing device is one or more special-purpose processing devices such as an application specific integrated circuit (ASIC), a field programmable gate array (FPGA), a digital signal processor (DSP), network processor, or the like. In some embodiments, the controller 110 includes a data storage device (e.g., one or more disk drives and/or solid state drives), a main memory, a static memory, a network interface, and/or other components. In some embodiments, the controller 110 executes instructions to perform any one or more of the methods or processes described herein. The instructions are stored on a computer readable storage medium, which include one or more of the main memory, static memory, secondary storage and/or processing device (during execution of the instructions). In some embodiments, controller 110 is used to control one or more parameters (e.g., temperature, pressure, flow rate, voltage, etc.) of the system 100. The controller 110 receives sensor data from one or more sensors associated with the system 100.

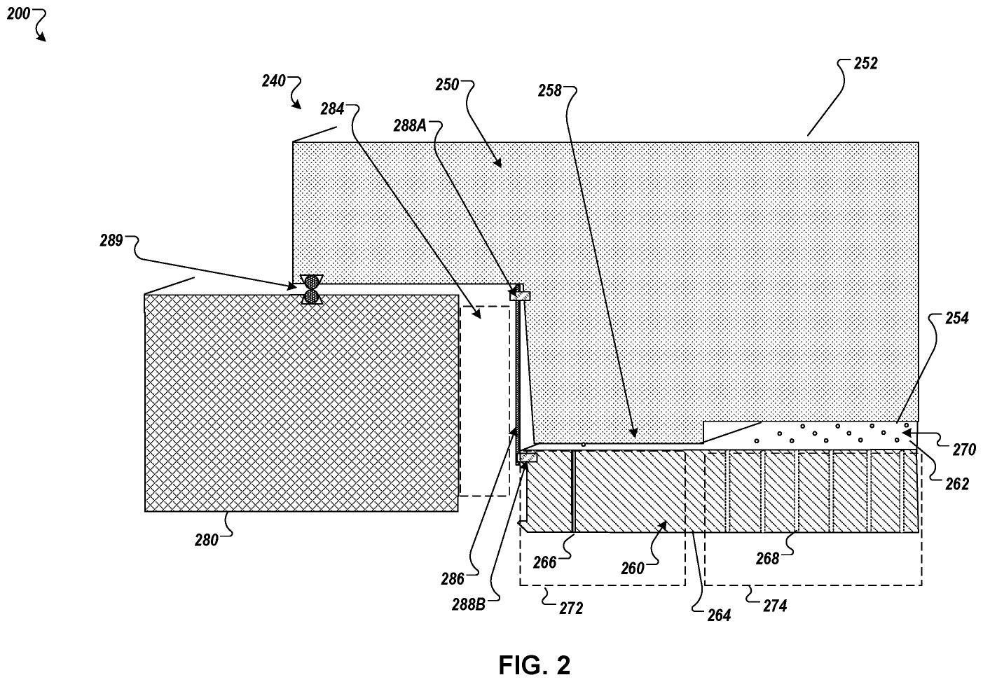

FIG. 2 illustrates a system 200 including a backing plate 250 (e.g., backing plate 150 of FIG. 1) and a diffuser plate 260 (e.g., diffuser plate 160 of FIG. 1), according to certain embodiments. Features with similar reference numbers compared to features in other FIGS. may include the same or similar structure and/or functionality.

Assembly 240 (e.g., assembly 140) includes backing plate 250 and diffuser plate 260.

Backing plate 250 has a backing plate upper surface 252 (e.g., backing plate upper surface 152 of FIG. 1) and a backing plate lower surface 254 (e.g., backing plate lower surface 154 of FIG. 1). Backing plate 250 forms a perimeter dead zone protrusion 258 (e.g., a perimeter dead zone protrusion 158 of FIG. 1) that surrounds a recess formed by the backing plate lower surface 254. In some embodiments, the perimeter dead zone protrusion 258 curves (e.g., side surface between perimeter dead zone protrusion 258 and recess is without sharp corners) to the recess of the backing plate 250.

In some embodiments, the backing plate 250 is disposed above the diffuser plate 260 without any fasteners (e.g., bolts) passing through the perimeter dead zone protrusion 258 and/or the diffuser plate upper surface 262. The backing plate 250 and the diffuser plate 260 of the present disclosure may be used for higher temperature processes and/or the backing plate 250 and diffuser plate 260 may be made of different materials compared to conventional solutions. Thermal expansion of backing plate 250 and diffuser plate 260 of the present disclosure causes less rubbing of the backing plate 250 and the diffuser plate 260 and less particle generation (e.g., because the backing plate lower surface 254 and the diffuser plate upper surface 262 are not fastened to each other) compared to conventional solutions.

In some embodiments, the backing plate 250 is disposed above the diffuser plate 260 without the backing plate lower surface 254 contacting the diffuser plate upper surface 262 (e.g., perimeter dead zone protrusion 258 does not contact the diffuser plate upper surface 262).

Diffuser plate 260 has a diffuser plate upper surface 262 (e.g., diffuser plate upper surface 162 of FIG. 1) and a diffuser plate lower surface 264 (e.g., diffuser plate lower surface 164 of FIG. 1). The diffuser plate 260 forms purge holes 266 (e.g., purge holes 166 of FIG. 1, perimeter purge holes) in a perimeter portion 272 (e.g., perimeter portion 172 of FIG. 1) of the diffuser plate 260. The diffuser plate 260 forms perforated area holes 268 (e.g., perforated area holes 168 of FIG. 1, cone holes) in a perforated portion 274 (e.g., perforated portion 174 of FIG. 1) of the diffuser plate 260. The perimeter portion 272 surrounds the perforated portion 274.

The assembly 240 forms an inner volume 270 (e.g., inner volume 170 of FIG. 1) between the backing plate lower surface 254 and the diffuser plate upper surface 262. Gas is to be provided via the backing plate gas channel to the inner volume 270 and from the inner volume 270 via the perforated area holes 268 to a substrate.

In some embodiments, the backing plate forms a perimeter dead zone protrusion 258 (e.g., filler, perimeter dead zone filler) that reduces a dead zone outside of the perforated area (e.g., perforated portion 274). The perimeter dead zone protrusion 258 may be about 1 to about 5 mm (e.g., about 3 mm) from the diffuser plate upper surface 262. The backing plate lower portion at the recess may be about 10 to about 20 mm (e.g., about 13 mm) from the diffuser plate upper surface 262. The purge holes 266 may be straight hole purge holes (e.g., straight hole perimeter purge holes). The perforated area holes 268 may be single perforated area holes.

In some embodiments, a lid body 280 is disposed below a portion of backing plate 250 and next to diffuser plate 260. One or more insulators 284 (e.g., Teflon insulators) may be disposed between a side of the lid body 280 and corresponding sides of backing plate 250 and diffuser plate 260. A skirt 286 may be secured (e.g., via fasteners 288) to backing plate 250 and diffuser plate 260 (e.g., to maintain the clearances between backing plate and 250 and diffuser plate 260, to secure backing plate 250 and diffuser plate 260 to each other). A fastener 288A may secure an upper portion of the skirt 286 to a side surface of the backing plate 250 and a fastener 288B may secure a lower portion of the skirt 286 to a side surface of the diffuser plate 260.

The assembly 240 may include one or more sealing components 289 (e.g., gasket, O-ring, etc.) disposed between the backing plate 250 and the lid body 280. The one or more scaling components 289 may be disposed at a perimeter portion of the backing plate 250 to avoid degrading of the scaling components 289 by gases provided into the inner volume 270. In some embodiments, a first O-ring is provided in a groove of the backing plate lower surface 254 and a second O-ring is provided in a groove of an upper surface of the lid body 280 (e.g., the first O-ring and the second O-ring contact each other).

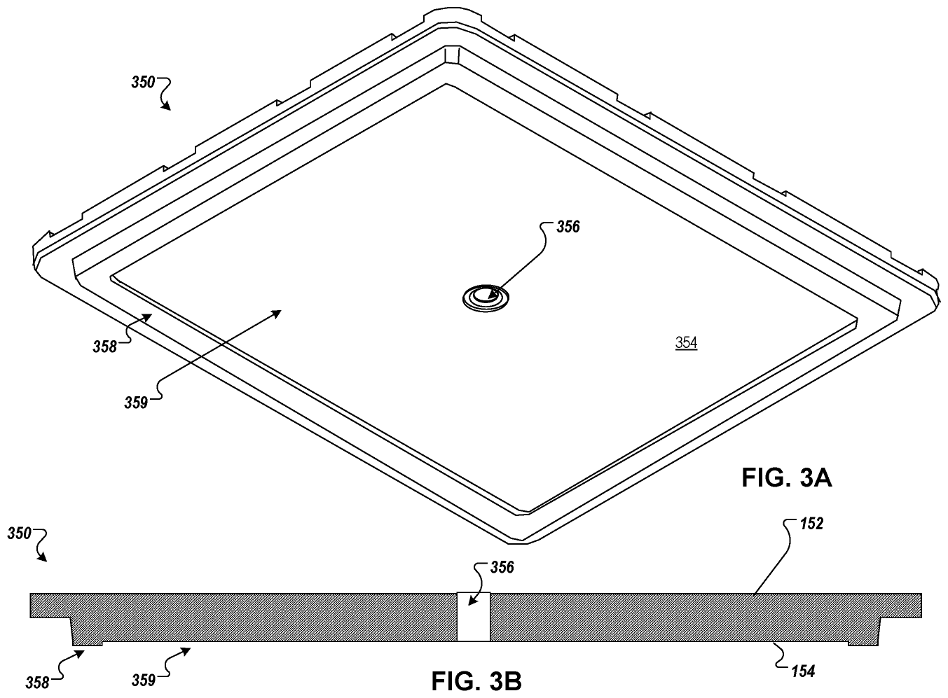

FIGS. 3A-B illustrates a backing plate 350 (e.g., backing plate 150 of FIG. 1, backing plate 250 of FIG. 2), according to certain embodiments. FIG. 3A illustrates a lower perspective view and FIG. 3B illustrates a side cross-sectional view. Features with similar reference numbers compared to features in other FIGS. may include the same or similar structure and/or functionality.

Backing plate 350 has a backing plate upper surface 352 (e.g., backing plate upper surface 152 of FIG. 1, backing plate upper surface 252 of FIG. 2) and a backing plate lower surface 354 (e.g., backing plate lower surface 154 of FIG. 1, backing plate lower surface 254 of FIG. 2). Backing plate 350 forms a perimeter dead zone protrusion 358 (e.g., a perimeter dead zone protrusion 158 of FIG. 1, perimeter dead zone protrusion 258 of FIG. 2) that surrounds a recess 359 formed by the backing plate lower surface 354. The backing plate may form one or more channels to receive fasteners (e.g., bolts) therethrough to mount the backing plate 350 to the diffuser plate.

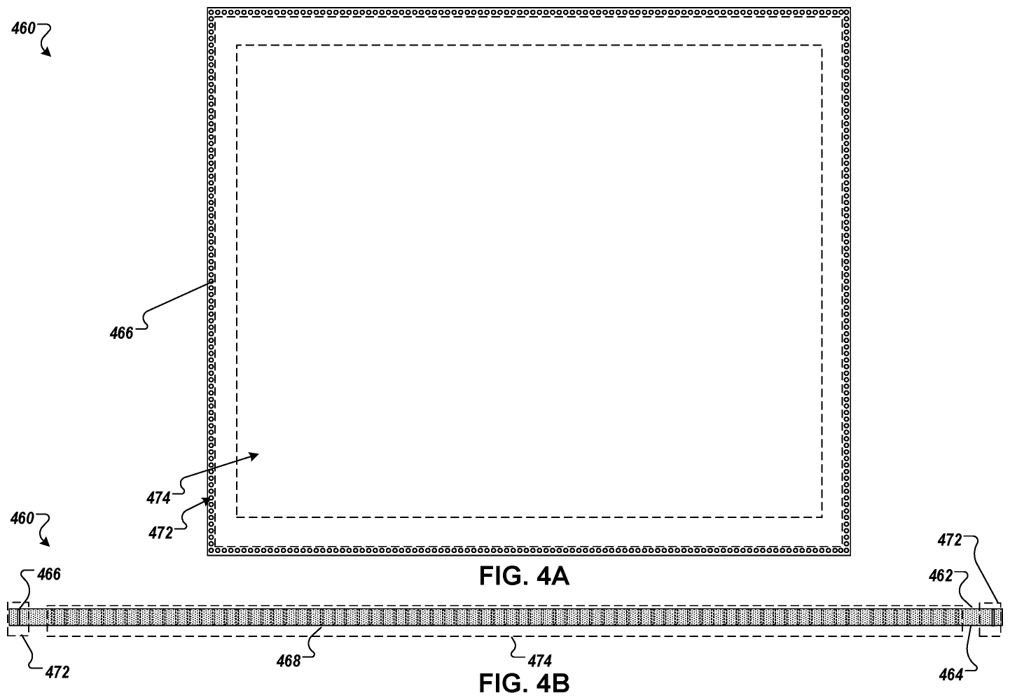

FIGS. 4A-B illustrate a diffuser plate 460 (e.g., diffuser plate 160 of FIG. 1, diffuser plate 260 of FIG. 2), according to certain embodiments. Features with similar reference numbers compared to features in other FIGS. may include the same or similar structure and/or functionality.

Diffuser plate 460 has a diffuser plate upper surface 462 (e.g., diffuser plate upper surface 162 of FIG. 1, diffuser plate upper surface 262 of FIG. 2) and a diffuser plate lower surface 464 (e.g., diffuser plate lower surface 164 of FIG. 1, diffuser plate lower surface 264 of FIG. 2). Diffuser plate 460 forms purge holes 466 (e.g., purge holes 166 of FIG. 1, purge holes 266 of FIG. 2, perimeter purge holes) in a perimeter portion 472 (e.g., perimeter portion 172 of FIG. 1, perimeter portion 272 of FIG. 2) of the diffuser plate 460. The diffuser plate 460 forms perforated area holes 468 (e.g., perforated area holes 168 of FIG. 1, perforated area holes 268 of FIG. 2, cone holes) in a perforated portion 474 (e.g., perforated portion 174 of FIG. 1, perforated portion 274 of FIG. 2) of the diffuser plate 460. The perimeter portion 472 surrounds the perforated portion 474. The perimeter portion 472 and/or purge holes 466 are configured to be disposed under the perimeter dead zone protrusion of the backing plate. The perforated portion 474 and/or perforated area holes 468 are configured to be disposed under the recess formed by the backing plate lower surface of the backing plate. The diffuser plate may form one or more recesses (e.g., blind holes, recesses that partially enter the diffuser plate upper surface 462 without passing through the diffuser plate 460) to receive fasteners (e.g., bolts) to mount the diffuser plate 460 to the backing plate.

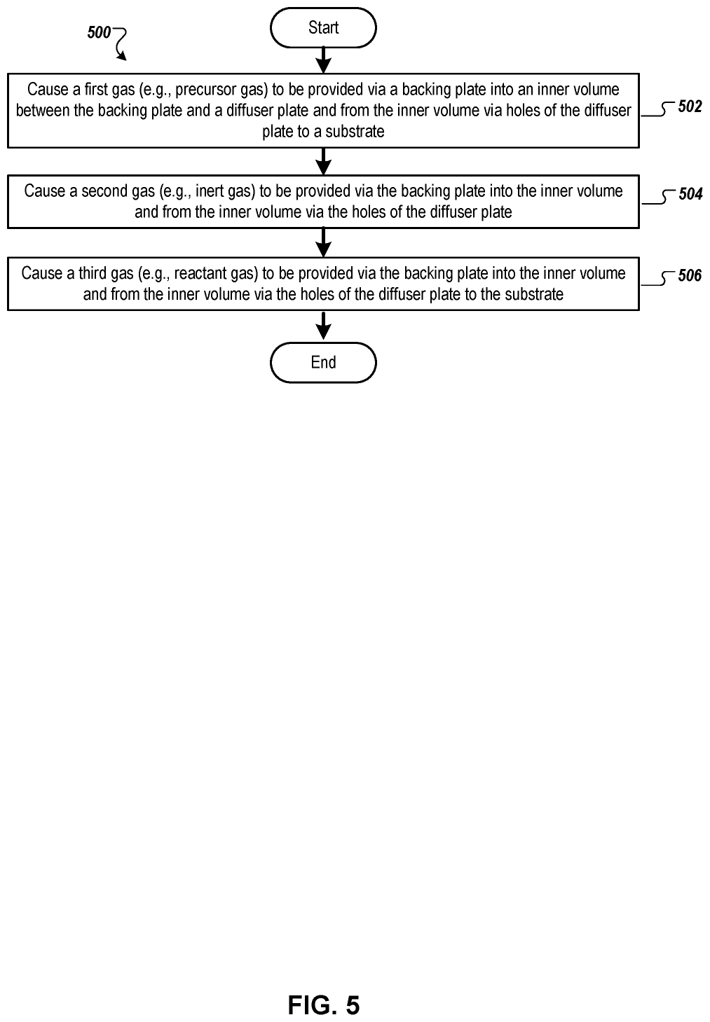

FIG. 5 illustrates a method of using a backing plate and diffuser plate assembly (e.g., system 100 of FIG. 1, assembly 140 of FIG. 1), according to certain embodiments. In some embodiments, one or more of operations of method 500 are performed by a controller (e.g., controller 110 of FIG. 1). Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment.

Referring to method 500 of FIG. 5, at block 502, a first gas is provided via the backing plate (e.g., backing plate 150 of FIG. 1) into an inner volume (e.g., inner volume 170 of FIG. 1) between the backing plate and the diffuser plate (e.g., diffuser plate 160 of FIG. 1) and from the inner volume via holes (e.g., perforated area holes 168 of FIG. 1, cone holes) of the diffuser plate to a substrate (e.g., substrate 120 of FIG. 1). In some embodiments, the first gas is a precursor. In some embodiments, the perimeter dead zone protrusion (e.g., perimeter dead zone protrusion 158 of FIG. 1) of the backing plate and/or the purge holes (e.g., purge holes 166 of FIG. 1, perimeter purge holes) of the diffuser plate cause less precursor gas to be retained proximate the perimeter portion (e.g., perimeter portion 172 of FIG. 1) of the diffuser plate (e.g., the portion of the diffuser plate where there are no perforated area holes) compared to conventional systems.

At block 504, a second gas is provided via the backing plate into the inner volume and from the inner volume via the holes (e.g., perforated area holes 168 and/or purge holes 166 of FIG. 1) of the diffuser plate to the substrate. In some embodiments, the second gas is an inert gas (e.g., nitrogen (N₂)). In some embodiments, block 504 is to flush the inner volume of the first gas (e.g., precursor). In some embodiments, the perimeter dead zone protrusion of the backing plate and/or the purge holes of the diffuser plate cause less precursor gas to be retained in the backing plate and diffuser plate assembly responsive to the flushing of the inner volume compared to conventional systems. The backing plate and diffuser plate of the present disclosure may improve purging performance for sequential ALD systems compared to conventional systems. The backing plate and diffuser plate of the present disclosure may form a thinner gap than conventional systems (e.g., conventional CVD tool) to further accelerate the purge process (e.g., flushing process, block 504). The dead zone height may be about 5% to about 50% (e.g., about 10% to about 50%, about 10% to about 20%, about 5% to about 25%, about 25% to about 50%, etc.) the height of the gap height. This may accelerate the purge flow in the gap so that the purge time or the gap is shorter and the process throughput is increased compared to conventional solutions. The purge holes in the diffuser plate may provide an exit for the residual gas in the dead zone between the backing plate and the diffuser plate to leave the dead zone. The perimeter dead zone protrusion (e.g., perimeter dead zone filler) on the backing plate may minimize the volume of dead zone so the purge for the dead zone is quicker.

At block 506, causing a third gas to be provided via the backing plate into the inner volume and from the inner volume via the holes of the diffuser plate to the substrate. In some embodiments, the second gas is a reactant gas (e.g., oxygen). In some embodiments, the perimeter dead zone protrusion of the backing plate and/or the purge holes of the diffuser plate avoids reaction of the reactant gas in the backing plate and diffuser plate assembly which causes less particle generation and less substrate defects.

The backing plate (e.g., backing plate with perimeter dead zone filler) and diffuser plate (e.g., diffuser plate with purge holes) of the present disclosure may increase the throughput of the top-down ALD tool. The backing plate and the diffuser plate of the present disclosure may provide a higher velocity of gas proximate the edges in the gap between the backing plate and the diffuser compared to conventional solutions. The backing plate and the diffuser plate of the present disclosure may provide a lower flow restriction of the diffuser plate compared to conventional solutions.

In some embodiments, the controller may use a shorter purge duration and lower purge flow rate via backing plate and the diffuser plate of the present disclosure to achieve a substantially complete purge result (e.g., higher purge efficiency) compared to conventional solutions.

In some embodiments, each of the operations of method 500 are performed while maintaining a sealed environment in the processing chamber.

Unless specifically stated otherwise, terms such as “causing,” determining,” “flowing,” “receiving,” “transmitting,” “generating,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and do not have an ordinal meaning according to their numerical designation.

Examples described herein also relate to an apparatus for performing the methods described herein. In some embodiments, this apparatus is specially constructed for performing the methods described herein, or it includes a general purpose computer system selectively programmed by a computer program stored in the computer system. In some embodiments, such a computer program is stored in a computer-readable tangible storage medium.

The methods and illustrative examples described herein are not inherently related to any particular computer or other apparatus. Various general purpose systems can be used in accordance with the teachings described herein, or a more specialized apparatus can be constructed to perform methods described herein and/or each of their individual functions, routines, subroutines, or operations. Examples of the structure for a variety of these systems are set forth in the description above.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure can practiced without these specific details. In other instances, well-known components or methods are not described in detail or are presented in simple block diagram format in order to avoid unnecessarily obscuring the present disclosure. Thus, the specific details set forth are merely exemplary. Particular implementations can vary from these exemplary details and still be contemplated to be within the scope of the present disclosure.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of operations of each method can be altered so that certain operations are performed in an inverse order so that certain operations are performed, at least in part, concurrently with other operations. In another embodiment, instructions or sub-operations of distinct operations are in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. An assembly comprising:
a backing plate; and
a diffuser plate configured to be disposed under the backing plate, wherein:
the diffuser plate forms a plurality of purge holes in a first region of the diffuser plate between a diffuser plate upper surface and a diffuser plate lower surface; and
the diffuser plate forms a plurality of perforated area holes in a second region of the diffuser plate between the diffuser plate upper surface and the diffuser plate lower surface, wherein each of the plurality of perforated area holes has a first width at the diffuser plate upper surface and a second width at the diffuser plate lower surface, wherein the second width is larger than the first width.

2. The assembly of claim 1, wherein:
the first region corresponds to a perimeter portion of the diffuser plate;
the second region corresponds to a perforated portion of the diffuser plate; and
the perimeter portion surrounds the perforated portion.

3. The assembly of claim 1, wherein:
the backing plate forms a backing plate gas channel from a backing plate upper surface to a backing plate lower surface;
the assembly forms an inner volume between the backing plate lower surface and the diffuser plate upper surface; and
gas is to be provided via the backing plate gas channel to the inner volume and from the inner volume via the plurality of perforated area holes to a substrate.

4. The assembly of claim 1, wherein a backing plate lower surface of the backing plate forms a perimeter dead zone protrusion configured to be disposed proximate the diffuser plate upper surface.

5. The assembly of claim 1, wherein:
each of the plurality of purge holes have a substantially uniform diameter; and
the plurality of purge holes are configured to provide an exit for residual gas in a dead zone between the backing plate and the diffuser plate.

6. The assembly of claim 1, wherein a backing plate lower surface of the backing plate forms a central recess configured to be disposed above a the second region of the diffuser plate that forms the plurality of perforated area holes.

7. The assembly of claim 1, wherein each of the plurality of perforated area holes comprises an upper uniform portion and a lower cone-shaped portion.

8. The assembly of claim 1, wherein a sequential Atomic Layer Deposition (ALD) system comprises the assembly.

9. An assembly comprising:
a diffuser plate; and
a backing plate configured to be disposed above the diffuser plate, wherein:
a backing plate lower surface of the backing plate forms perimeter dead zone protrusion;
the backing plate lower surface forms a recess surrounded by the perimeter dead zone protrusion; and
a dead zone height between a diffuser plate upper surface of the diffuser plate and the perimeter dead zone protrusion is smaller than a gap height between the diffuser plate upper surface and the backing plate lower surface at the recess.

10. The assembly of claim 9, wherein the dead zone height is about 1 to about 5 millimeters.

11. The assembly of claim 9, wherein the dead zone height is about 10% to about 25% the gap height.

12. The assembly of claim 9, wherein the diffuser plate forms a plurality of purge holes that are configured to be below the perimeter dead zone protrusion.

13. The assembly of claim 9, wherein the diffuser plate forms a plurality of perforated area holes that are configured to be below the recess.

14. The assembly of claim 9, wherein:
the backing plate forms a backing plate gas channel from a backing plate upper surface to the backing plate lower surface;
the assembly forms an inner volume between the backing plate lower surface and the diffuser plate upper surface; and
gas is to be provided via the backing plate gas channel to the inner volume and from the inner volume via the diffuser plate to a substrate.

15. An assembly comprising:
a backing plate comprising a backing plate lower surface that forms a perimeter dead zone protrusion; and
a diffuser plate configured to be disposed under the backing plate, wherein:
the diffuser plate forms a plurality of purge holes between a diffuser plate upper surface and a diffuser plate lower surface; and
the plurality of purge holes are configured to be disposed under the perimeter dead zone protrusion.

16. The assembly of claim 15, wherein the diffuser plate forms a plurality of perforated area holes between the diffuser plate upper surface and the diffuser plate lower surface.

17. The assembly of claim 16, wherein:
the backing plate forms a backing plate gas channel from a backing plate upper surface to the backing plate lower surface;
the assembly forms an inner volume between the backing plate lower surface and the diffuser plate upper surface; and
gas is to be provided via the backing plate gas channel to the inner volume and from the inner volume via the plurality of perforated area holes to a substrate.

18. The assembly of claim 16, wherein:
each of the plurality of purge holes have a substantially uniform diameter; and
the plurality of purge holes are configured to provide an exit for residual gas in a dead zone between the backing plate and the diffuser plate.

19. The assembly of claim 16, wherein each of the plurality of perforated area holes comprises an upper uniform portion and a lower cone-shaped portion.

20. The assembly of claim 16, wherein a dead zone height is between the diffuser plate upper surface of the diffuser plate and the perimeter dead zone protrusion, and wherein the dead zone height is about 1 to about 5 millimeters.
